(19) United States
(12) Patent Application Publication
(10) Pub. No.: US 2026/0305271 A1
(43) Pub. Date: Oct. 1, 2026

(54) WAFER PROCESSING METHOD AND DEVICE CHIP MANUFACTURING METHOD

(71) Applicant: DISCO CORPORATION, Tokyo (JP)

(72) Inventors: Kokichi MINATO, Tokyo (JP); Koichi MAKINO, Tokyo (JP)

(21) Appl. No.: 19/554,767

(22) Filed: Mar. 3, 2026

(30) Foreign Application Priority Data
Mar. 31, 2025 (JP) 2025-057698

(51) Int. Cl. H10P 90/00; H10P 10/00; H10P 58/00

(52) U.S. Cl. CPC H10P 90/128; H10P 10/128; H10P 58/00

(57) ABSTRACT

A wafer processing method includes chamfer removing at least a part of a chamfer of a first wafer in annular shape along an outer periphery of the first wafer; bonding a first face of the first wafer with a second wafer; grinding the second face of the first wafer by using a grinding wheel which includes grinding stones arranged annularly, after the chamfer removing and the bonding; corner processing of processing, after the grinding, a corner of the outer peripheral end of the first wafer on the second face side ground in the grinding, such that thickness thereof gradually decreases outward in a diameter direction; and resin layer forming by applying liquid resin onto the second face of the first wafer, after the corner processing.

### BACKGROUND

### 1. Technical Field

The present disclosure relates to a wafer processing method and a device chip manufacturing method.

### 2. Description of the Related Art

A chamfer may be formed on an outer peripheral end of a wafer, on the first face of which a plurality of devices are formed. In a case where a second face side of the wafer, on which the chamfer is formed, is ground so as to thin the wafer, the chamfer becomes a sharp edge. Then cracks are more easily generated from the outer periphery of the wafer toward the inside thereof, and the device may be damaged. To prevent this, a technique is known in which the chamfer is removed in advance so that the sharp edge is not generated even if the wafer is ground (see JP 2000-173961 A). Further, even in a case of a bonded wafer in which a first wafer and a second wafer are bonded, a chamfer of the first wafer is removed in advance, then the first wafer is ground and thinned.

### SUMMARY

However, a problem of forming a resin layer by applying a liquid resin onto a ground face of the wafer, which was subjected to grinding, is that the thickness of the resin layer is not uniform. As illustrated in FIG. 1, on the wafer W after grinding, a corner W3 between a ground face W1 and a side face W2 is a right angle, hence the resin layer R rises at the outer peripheral end of the wafer W due to the influence of surface tension which acts on the liquid resin, whereby a portion Ra where the thickness of the resin layer R is relatively large, and a portion Rb where the thickness of the resin layer R is relatively small, are formed. If the resin layer R is a resist film, for example, a non-uniform thickness of the resin layer R causes problems such as exposure defects, and an increase in the time to remove the resist film.

It is an object of the present disclosure to provide a wafer processing method and a device chip manufacturing method, with which the resin layer can be formed uniformly on the ground face of the wafer, which was subjected to grinding.

The present disclosure provides a following wafer processing method to solve the above problem, that is, a wafer processing method for processing a first wafer which includes a first face and a second face on an opposite side to the first face, and in which a chamfer is formed on an outer peripheral end, the method including:
chamfer removing at least a part of the chamfer of the first wafer in annular shape along an outer periphery of the first wafer;
bonding the first face of the first wafer with a second wafer;
grinding the second face of the first wafer by using a grinding wheel which includes grinding stones arranged annularly, after the chamfer removing and the bonding;
corner processing of processing, after the grinding, a corner of the outer peripheral end of the first wafer on the second face side ground in the grinding, such that thickness thereof gradually decreases outward in a diameter direction; and
resin layer forming by applying liquid resin onto the second face of the first wafer, after the corner processing.

It is preferable that the bonding is performed after the chamfer removing. The bonding may be performed before the chamfer removing.

In the corner processing, it is preferable that the corner is processed by using the grinding wheel, by relatively moving the grinding wheel and the first wafer. In the corner processing, the corner may be processed by using an annular cutting blade having a cutting edge on an outer periphery, by relatively moving the cutting blade and the first wafer. In the corner processing, the corner may be processed along with polishing the second face of the first wafer by using a polishing pad.

The present disclosure provides a following device chip manufacturing method to solve the above problem, that is, a device chip manufacturing method, the method including:
chamfer removing at least a part of a chamfer of a first wafer in annular shape along an outer periphery of the first wafer, the first wafer including a first face on which a device is formed in each of a plurality of regions demarcated by a plurality of division lines, and a second face on an opposite side to the first face, and the chamfer being formed on an outer peripheral end of the first wafer;
bonding the first wafer of the first face with a second wafer;
grinding the second face of the first wafer by using a grinding wheel which includes grinding stones arranged annularly, after the chamfer removing and the bonding;
corner processing of processing, after the grinding, a corner of the outer peripheral end of the first wafer on the second face side ground in the grinding, such that thickness thereof gradually decreases outward in a diameter direction;
resin layer forming by applying liquid resin onto the second face of the first wafer, after the corner processing; and
manufacturing device chips by dividing the first wafer and the second wafer along the division lines on the first wafer, after the resin layer forming.

The wafer processing method of the present disclosure is a wafer processing method for processing a first wafer which includes a first face and a second face on an opposite side to the first face, and in which a chamfer is formed on an outer peripheral end, the method including:
chamfer removing at least a part of the chamfer of the first wafer in annular shape along an outer periphery of the first wafer; bonding the first face of the first wafer with a second wafer;
grinding the second face of the first wafer by using a grinding wheel which includes grinding stones arranged annularly, after the chamfer removing and the bonding;
corner processing of processing, after the grinding, a corner of the outer peripheral end of the first wafer on the second face side ground in the grinding, such that thickness thereof gradually decreases outward in a diameter direction; and
resin layer forming by applying liquid resin onto the second face of the first wafer, after the corner processing. Therefore the resin layer can be uniformly formed on the ground face of the wafer after the grinding.

The device chip manufacturing method of the present disclosure is a device chip manufacturing method, including:
chamfer removing at least a part of a chamfer of a first wafer in annular shape along an outer periphery of the first wafer, the first wafer including a first face on which a device is formed in each of a plurality of regions demarcated by a plurality of division lines, and a second face on an opposite side to the first face, and the chamfer being formed on an outer peripheral end of the first wafer;
bonding the first face of the first wafer with a second wafer; grinding the second face of the first wafer by using a grinding wheel which includes grinding stones arranged annularly, after chamfer removing and the bonding;
corner processing of processing, after the grinding, a corner of outer peripheral end of the first wafer on the second face side ground in the grinding, such that thickness thereof gradually decreases outward in a diameter direction;
resin layer forming by applying liquid resin onto the second face of the first wafer, after the corner processing; and
manufacturing device chips by dividing the first wafer and the second wafer along the division lines on the first wafer, after the resin layer forming. Therefore the resin layer can be uniformly formed on the ground face of the wafer, which was ground.

### BRIEF DESCRIPTION OF THE DRAWINGS

FIG. 1 is a schematic diagram depicting a case where a resin layer is formed on a ground face of a wafer based on a prior art;

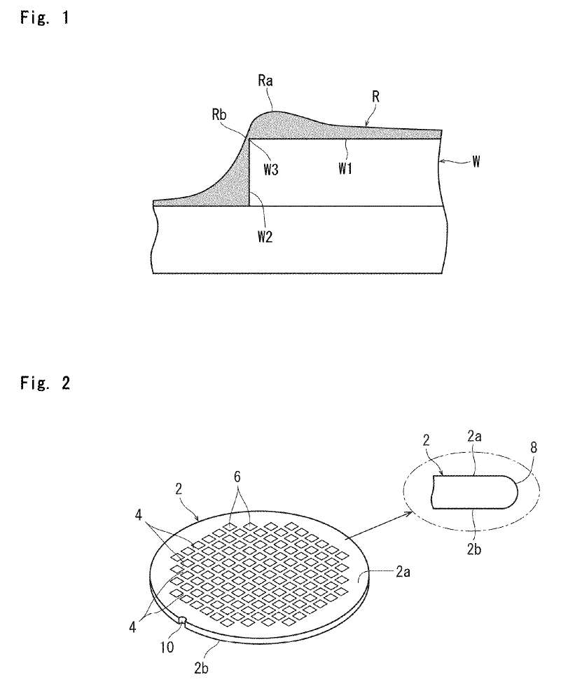

FIG. 2 is a perspective view of a first wafer;

FIG. 3A is a schematic diagram depicting chamfer removing, and FIG. 3B is a perspective view of the first wafer after a part of the chamfer is removed annularly along the outer periphery;

FIG. 4A is a schematic diagram depicting bonding, and FIG. 4B is a cross-sectional view of a bonded wafer in which a first wafer and a second wafer are bonded;

FIG. 5A is a schematic diagram depicting grinding, and FIG. 5B is a perspective view of the bonded wafer after the grinding;

FIG. 6A is a schematic diagram depicting a case of corner processing by using a grinding wheel, FIG. 6B is a partial cross-sectional view of a bonded wafer in which an inclined face is formed at a corner, and FIG. 6C is a partial cross-sectional view of a bonded wafer in which a curved face is formed at a corner;

FIG. 7 is a schematic diagram depicting a case of performing the corner processing by using a cutting blade;

FIG. 8 is a schematic diagram depicting a case of performing the corner processing by using a polishing pad;

FIG. 9A is a schematic diagram depicting resin layer forming, FIG. 9B is a partial cross-sectional view of a bonded wafer in a case of forming a resin layer on a bonded wafer in which an inclined face is formed at a corner, and FIG. 9C is a partial cross-sectional view of a bonded wafer in a case of forming a resin layer on a bonded wafer in which a curved face is formed at a corner;

FIG. 10A is a schematic diagram depicting a case of the bonding before performing the chamfer removing, FIG. 10B is a cross-sectional view of a bonded wafer, and FIG. 10C is a schematic diagram depicting a case of removing of the chamfer after the bonding;

FIG. 11A is a partial cross-sectional view of a cutting blade of which first side face is inclined, FIG. 11B is a partial cross-sectional view of a cutting blade of which first and second side faces are both inclined, FIG. 11C is a partial cross-sectional view of a first wafer in which a part of a chamfer is annularly removed along a outer periphery using the cutting blade illustrated in FIGS. 11A or 11B, 11D is a partial cross-sectional view of a bonded wafer in a case of the grinding after the bonding on the first wafer illustrated in FIGS. 11C, 11E is a partial cross-sectional view of a bonded wafer in a case of processing of a corner on the bonded wafer illustrated in FIGS. 11D, and 11F, is a partial cross-sectional view of a bonded wafer in a case of forming the resin layer on the bonded wafer illustrated in FIG. 11E;

FIG. 12A is a partial cross-sectional view of a bonded wafer, FIG. 12B is a schematic plan view of the bonded wafer illustrated in FIG. 12A in a case of removing the chamfer on the first wafer, FIG. 12C is a partial cross-sectional view of a bonded wafer in which all of the chamfer of the first wafer is annularly removed along a outer periphery using the method illustrated in FIGS. 12B, 12D is a partial cross-sectional view of a bonded wafer in a case of the grinding on the bonded wafer illustrated in FIGS. 12C, 12E is a partial cross-sectional view of a bonded wafer in a case of processing of the corner on the bonded wafer illustrated in FIGS. 12D, and 12F is a partial cross-sectional view of a bonded wafer in a case of forming of the resin layer on the bonded wafer illustrate in FIG. 12E; and

FIG. 13A is a schematic diagram depicting a case of removing of the chamfer by applying a laser beam onto the first wafer before bonding, and FIG. 13B is a schematic diagram depicting a case of removing of the chamfer by applying a laser beam onto the first wafer of the bonded wafer.

### DESCRIPTION OF THE PREFERRED EMBODIMENTS

Embodiments of a wafer processing method and a device chip manufacturing method of the present disclosure will be described with reference to the drawings.

### First Wafer 2

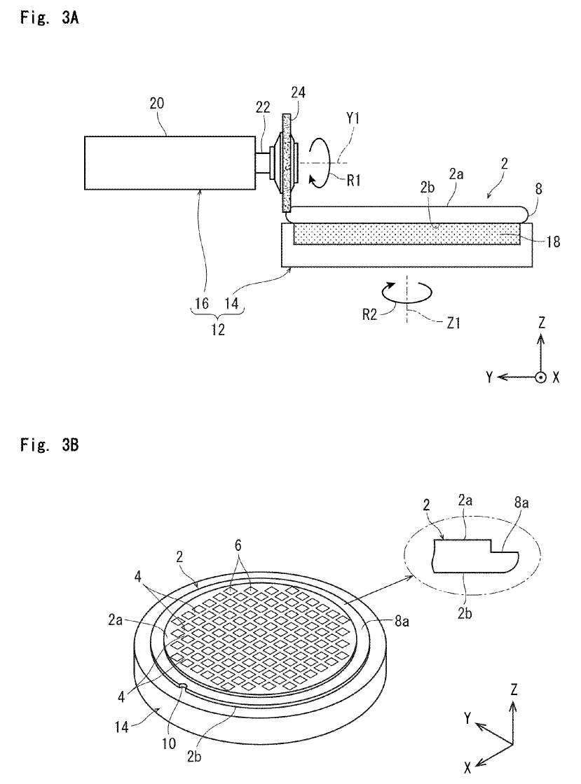

In FIG. 2, a disk-shaped first wafer 2 to be processed by the method of the present disclosure is illustrated. The first wafer 2 includes a circular first face 2a and a circular second face 2b on an opposite side of the first face 2a. The first wafer 2 is formed of a semiconductor material (e.g., silicon, silicon carbide). The first face 2a of the first wafer 2 is demarcated into a plurality of regions by a plurality of division lines 4, and a device 6, such as an integrated circuit (IC), is formed in each of the demarcated regions. On an outer peripheral end of the first wafer 2, a chamfer 8 is formed, and a notch 10, to indicate crystal orientation, is formed.

### Chamfer Removing

In the present embodiment, chamfer removing at least a part of the chamfer 8 of the first wafer 2 in annular shape along a outer periphery of the first wafer 2 is performed.

### Cutting Apparatus 12

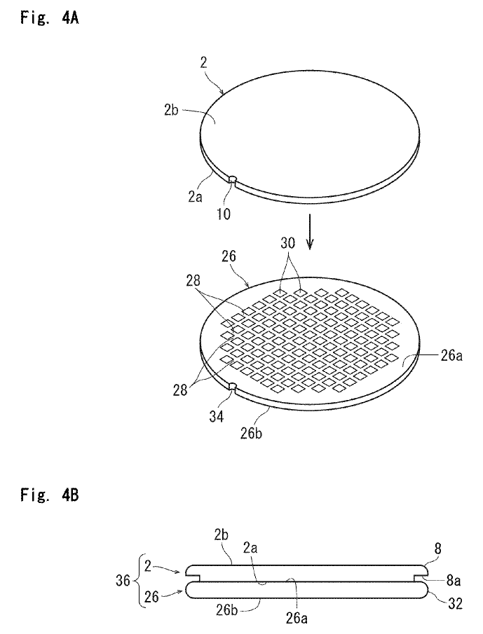

The chamfer removing can be performed using a cutting apparatus 12 illustrated in FIG. 3A, for example. The cutting apparatus 12 includes: a chuck table 14 which holds a workpiece; and a cutting unit 16 which cuts the workpiece held by the chuck table 14.

### Chuck Table 14 of Cutting Apparatus 12

A disc-shaped suction chuck 18 is disposed at an upper end of the chuck table 14. The suction chuck 18 is formed of a porous member (e.g., porous ceramics), and is connected to a suction pump (not illustrated). In the chuck table 14, a suction force is generated on an upper face of the suction chuck 18 using the suction pump, whereby the workpiece placed on the upper face of the chuck table 14 is suction-held. The chuck table 14 is rotatable around a shaft line Z1, which extends in the Z axis direction passing through the center of the suction chuck 18.

### Cutting Unit 16 of Cutting Apparatus 12

The cutting unit 16 includes: a spindle housing 20 which is movable in the Y axis direction and the Z axis direction; a spindle 22 which is supported by the spindle housing 20 so as to be rotatable around a shaft line Y1 which extends in the Y axis direction; and an annular cutting blade 24 which is fixed at a tip of the spindle 22. A cutting edge of an outer periphery of the cutting blade 24 may be made of abrasive grains (e.g., diamonds) bonded by bonding material (e.g., metal bond, resin bond). A thickness of the cutting edge of the cutting blade 24 is preferably a thickness of about 2 mm to 3 mm, for example, with which at least a part of the chamfer 8 of the first wafer 2 can be annularly removed along the outer periphery of the first wafer 2.

In the chamfer removing, the first face 2a is directed upward and the first wafer 2 is suction-held on the upper face of the chuck table 14. Here the center of the first wafer 2 is matched with the shaft line Z1. Then the spindle housing 20 or the chuck table 14 is moved so that the cutting blade 24 is positioned above the chamfer 8 of the first wafer 2. Then the cutting blade 24 is rotated in a direction indicated by an arrow R1 in FIG. 3A. Then the cutting edge of the cutting blade 24 is cut into the chamfer 8 of the first wafer 2 at least at a depth of a predetermined finishing thickness, and while supplying cutting water (e.g., pure water), the chuck table 14 is rotated in a direction indicated by an arrow R2 in FIG. 3A. Thereby a part of the chamfer 8 (a part of the chamfer 8 on the first face 2a side in the example in FIG. 3B) can be annularly removed along the outer periphery of the first wafer 2. In FIG. 3B, the portion, in which a part of the chamfer 8 was removed, is indicated by a reference sign 8a.

### Bonding

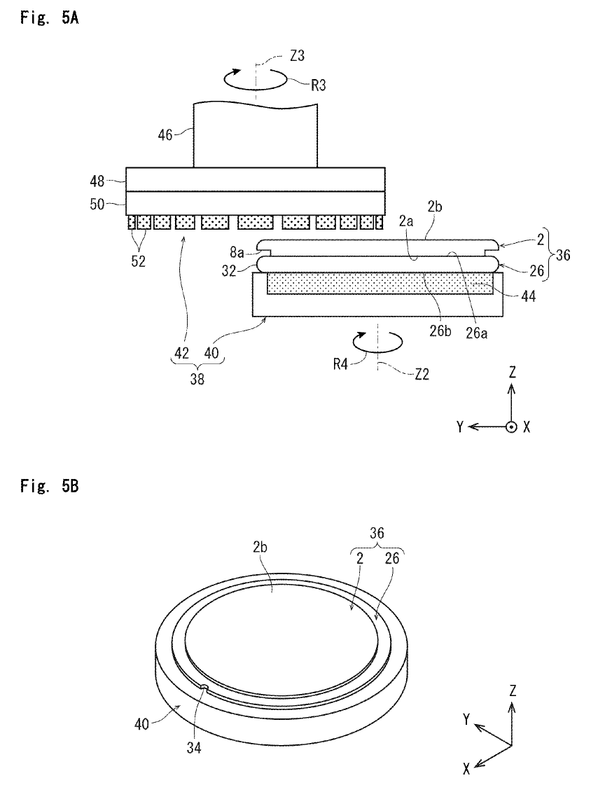

After the chamfer removing, bonding the first face 2a of the first wafer 2 with a second wafer 26 is performed, as illustrated in FIGS. 4A and 4B.

A configuration of the second wafer 26 which is bonded with the first wafer 2 may be the same as the configuration of the first wafer 2. In the present embodiment, as illustrated in FIG. 4A, the disc-shaped second wafer 26 includes a circular first face 26a and a circular second face 26b on the opposite side of the first face 26a. A diameter of the second wafer 26 is the same as the diameter of the first wafer 2. A material of the second wafer 26 is the same as the material of the first wafer 2 (e.g., silicon, silicon carbide). The first face 26a of the second wafer 26 is demarcated into a plurality of regions by a plurality of division lines 28, and a device 30 is formed on each of the demarcated regions. On an outer peripheral end of the second wafer 26, a chamfer 32 is formed, and a notch 34, to indicate crystal orientation, is formed. The configuration of the second wafer 26 may not be the same as the configuration of the first wafer 2. For example, the devices 30 may not be formed on the first face 26a or the material, diameter, and the like of the second wafer 26 may be different from the material, diameter, and the like of the first wafer 2.

In the bonding, the first face 2a of the first wafer 2 and the first face 26a of the second wafer 26 are bonded. To perform the bonding, the notch 10 of the first wafer 2 and the notch 34 of the second wafer 26 are aligned, so that the crystal orientation of the first wafer 2 and the crystal orientation of the second wafer 26 match. The bonding method to bond the first wafer 2 and the second wafer 26 may be a known method. Hereafter a wafer generated by bonding the first wafer 2 and the second wafer 26 will be referred to as a “bonded wafer 36”.

### Grinding

After the chamfer removing, grinding the second face 2b of the first wafer 2 is performed using a grinding wheel which includes grinding stones arranged annularly.

### Grinding Apparatus 38

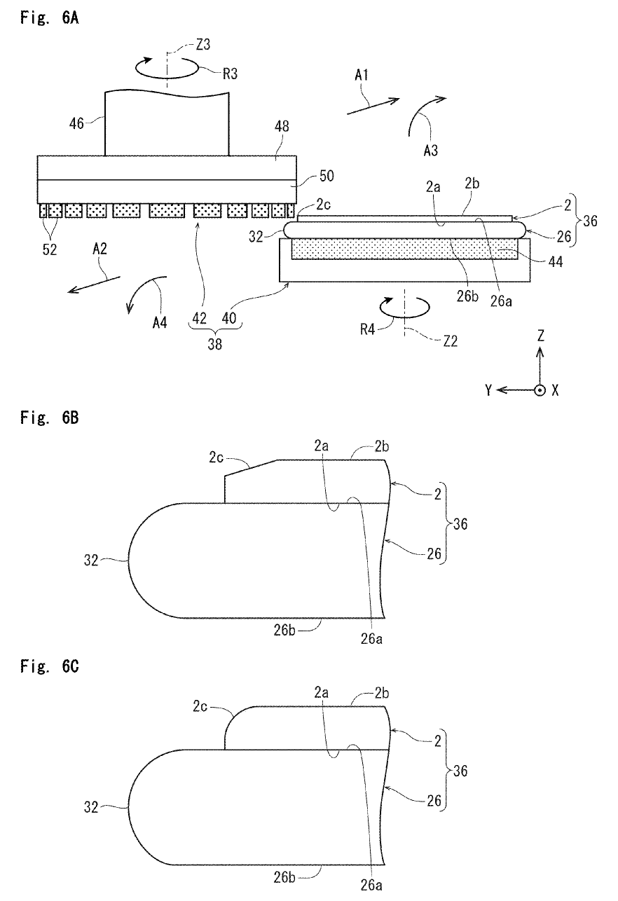

The chamfer removing can be performed using a grinding apparatus 38 illustrated in FIG. 5A, for example. The grinding apparatus 38 includes: a chuck table 40 which holds a workpiece; and a grinding unit 42 which grinds the workpiece held by the chuck table 40.

### Chuck Table 40 of Grinding Apparatus 38

A disc-shaped suction chuck 44 is disposed at an upper end of the chuck table 40. The suction chuck 44 is formed of a porous member (e.g., porous ceramics), and is connected to a suction pump (not illustrated). In the chuck table 40, a suction force is generated on an upper face of the suction chuck 44 using the suction pump, whereby the workpiece placed on the upper face of the chuck table 40 is suction-held. The chuck table 40 is rotatable around a shaft line Z2 which extends in the Z axis direction passing through the center of the suction chuck 44.

### Grinding Unit 42 of Grinding Apparatus 38

The grinding unit 42 includes: a spindle 46 which is rotatable around a shaft line Z3 which extends in the Z axis direction; a disc-shaped wheel mount 48 which is fixed at a lower end of the spindle 46; and an annular grinding wheel 50 which is fastened to a lower face of the wheel mount 48. On the periphery of the lower face of the grinding wheel 50, a plurality of grinding stones 52, which are annularly arranged at intervals in the circumferential direction, are fixed. The grinding stones 52 may be grinding stones on which abrasive grains (e.g., diamonds) are bonded by bonding material (e.g., metal bond, resin bond).

In the grinding, the second face 2b of the first wafer 2 is directed upward and the bonded wafer 36 is suction-held on the upper face of the chuck table 40. Here the center of the first wafer 2 is matched with the shaft line Z2. Then the spindle 46 is rotated in a direction indicated by an arrow R3 in FIG. 5A, and the chuck table 40 is rotated in a direction indicated by an arrow R4 in FIG. 5A. Then the spindle 46 is lowered so that the grinding stones 52 are contacted with the second face 2b of the first wafer 2, while supplying grinding water (e.g., pure water). Then the spindle 46 is lowered at a predetermined grinding feed speed. Thereby, as illustrated in FIG. 5B, the second face 2b of the first wafer 2 is ground, and the first wafer 2 is thinned to the predetermined finishing thickness. In the chamfer removing, the chamfer 8 of the first wafer 2 on the first face 2a side was removed to at least a depth of the predetermined finishing thickness. Hence the chamfer 8 of the first wafer 2 is completely removed by the grinding.

### Corner Processing

After the grinding, processing a corner 2c of the outer peripheral end of the first wafer 2 on the second face 2b side ground in the grinding, is performed, such that thickness thereof gradually decreases outward in a diameter direction.

### Corner Processing Using Grinding Apparatus 38

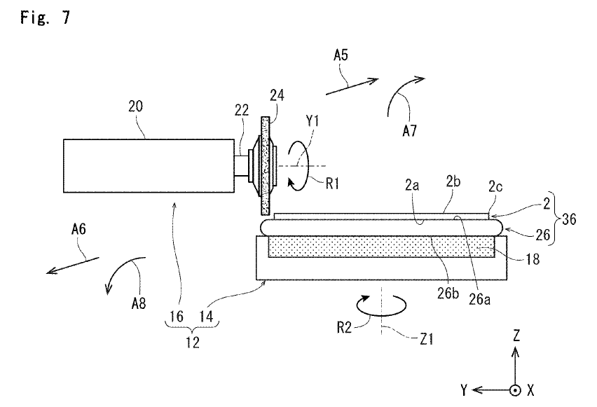

The corner processing can be performed using the grinding apparatus 38 described above, for example. To perform the corner processing using the grinding apparatus 38, the bonded wafer 36 is suction-held by the chuck table 40, and the spindle 46 or the chuck table 40 is moved in this state, so that the grinding stones 52 are positioned at the outer side of the first wafer 2 in the diameter direction, as illustrated in FIG. 6A. Then the spindle 46 is rotated in a direction indicated by the arrow R3, and the chuck table 40 is rotated in a direction indicated by the arrow R4. Then the grinding wheel 50 and the first wafer 2 are relatively moved, so as to process the corner 2c using the grinding stones 52 of the grinding wheel 50. In other words, the grinding wheel 50 is linearly moved in a direction indicated by an arrow A1, or the chuck table 40 is linearly moved in a direction indicated by an arrow A2, so that the grinding stones 52 are contacted with the corner 2c at the outer peripheral end of the first wafer 2 on the second face 2b side, while supplying the grinding water. Thereby, as illustrated in FIG. 6B, the corner 2c at the outer peripheral end is ground, and the corner 2c is processed (C chamfering) such that the thickness gradually decreases outward in the diameter direction of the first wafer 2.

To perform the corner processing using the grinding apparatus 38, the grinding wheel 50 is moved so as to draw an arc in a direction indicated by an arrow A3, instead of in the direction indicated by the arrow A1, or the chuck table 40 is moved so as to draw an arc in a direction indicated by an arrow A4, instead of in the direction indicated by the arrow A2, so that the grinding stones 52 are contacted with the corner 2c at the outer peripheral end of the first wafer 2 on the second face 2b side, while supplying the grinding water. Thereby, as illustrated in FIG. 6C, the corner 2c at the outer peripheral end is ground, and the corner 2c is processed (R chamfering) such that the thickness gradually decreases outward in the diameter direction of the first wafer 2.

### Corner Processing Using Cutting Apparatus 12

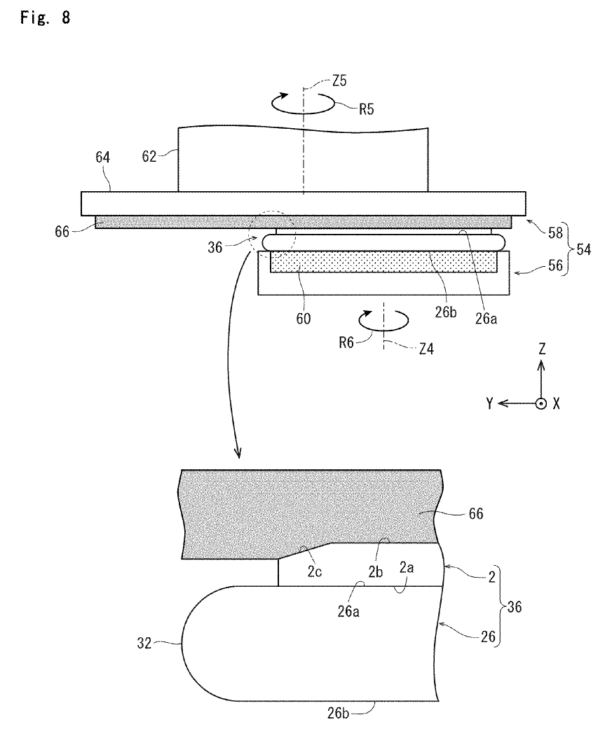

The corner processing can also be performed using the cutting apparatus 12. To perform the corner processing using the cutting apparatus 12, the second face 2b of the first wafer 2 is directed upward, and the bonded wafer 36 is suction-held on the upper face of the chuck table 14. Here the center of the first wafer 2 is matched with the shaft line Z1. Then the spindle housing 20 or the chuck table 14 is moved so that the cutting blade 24 is positioned at the outer side of the first wafer 2 in the diameter direction, as illustrated in FIG. 7. Then the cutting blade 24 is rotated in a direction indicated by the arrow R1, and the chuck table 14 is rotated in a direction indicated by an arrow R2. Then the cutting blade 24 and the first wafer 2 are relatively moved so as to process the corner 2c using the cutting edge of the cutting blade 24. In other words, the cutting blade 24 is linearly moved in a direction indicated by an arrow A5, or the chuck table 14 is linearly moved in a direction indicated by an arrow A6, so that the cutting edge of the cutting blade 24 is contacted with the corner 2c at the outer peripheral end of the first wafer 2 on the second face 2b side, while supplying the cutting water. Thereby the corner 2c at the outer peripheral end is cut, and the corner 2c is processed (C chamfering) such that the thickness gradually decreases outward in the diameter direction of the first wafer 2 (see FIG. 6B).

To perform the corner processing using the cutting apparatus 12, the cutting blade 24 is moved so as to draw an arc in a direction indicated by an arrow A7, instead of in the direction indicated by the arrow A5, or the chuck table 14 is moved so as to draw an arc in a direction indicated by an arrow A8, instead of in the direction indicated by the arrow A6, so that the cutting edge of the cutting blade 24 is contacted with the corner 2c at the outer peripheral end of the first wafer 2 on the second face 2b side, while supplying the cutting water. Thereby the corner 2c at the outer peripheral end is cut, and the corner 2c is processed (R chamfering) such that the thickness gradually decreases outward in the diameter direction of the first wafer 2 (see FIG. 6C).

### Polishing Apparatus 54

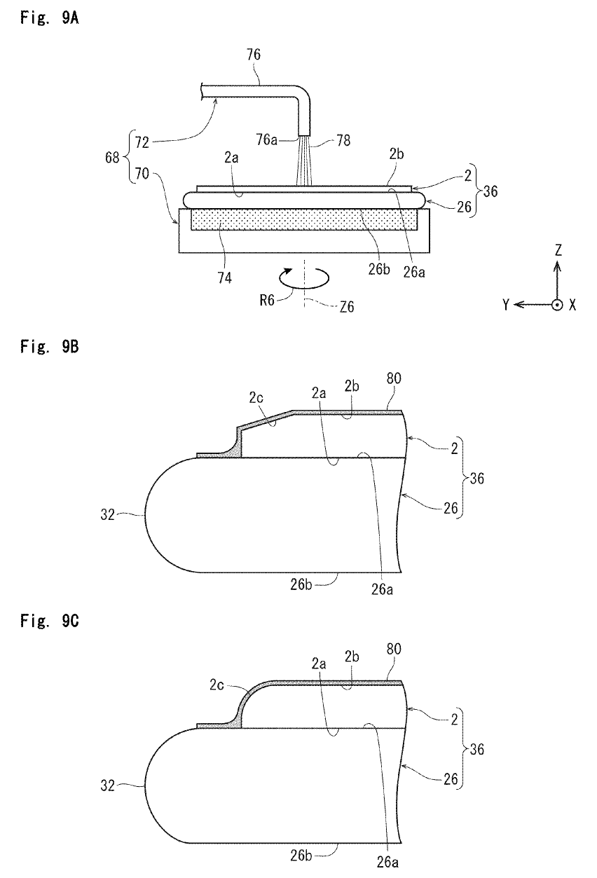

The corner processing can also be performed using a polishing apparatus 54 illustrated in FIG. 8. The polishing apparatus 54 includes: a chuck table 56 which holds a workpiece; and a polishing unit 58 which grinds the workpiece held by the chuck table 56.

### Chuck Table 56 of Polishing Apparatus 54

A disc-shaped suction chuck 60 is disposed at an upper end of the chuck table 56. The suction chuck 60 is formed of a porous member (e.g., porous ceramics), and is connected to a suction pump (not illustrated). In the chuck table 56, suction force is generated on an upper face of the suction chuck 60 using the suction pump, whereby the workpiece placed on the upper face of the chuck table 56 is suction-held. The chuck table 56 is rotatable around a shaft line Z4 which extends in the Z axis direction, passing through the center of the suction chuck 60.

### Polishing Unit 58 of Polishing Apparatus 54

The polishing unit 58 includes: a spindle 62 which is rotatable around a shaft line Z5 which extends in the Z axis direction; a disc-shaped pad mount 64 which is fixed at a lower end of the spindle 62; and a disc-shaped polishing pad 66 which is fixed to the lower face of the pad mount 64. As illustrated in FIG. 8, the diameter of the polishing pad 66 is larger than the diameter of the bonded wafer 36. The polishing pad 66 may be formed of a synthetic resin (e.g., polyurethane) containing abrasive grains (e.g., diamonds), or non-woven fabric (e.g., felt) containing abrasive grains.

### Corner Processing Using Polishing Apparatus 54

To perform the corner processing using the polishing apparatus 54, the second face 2b of the first wafer 2 is directed upward, and the bonded wafer 36 is suction-held on the upper face of the chuck table 56. Then the spindle 62 is rotated in a direction indicated by an arrow R5, and the chuck table 56 is rotated in a direction indicated by an arrow R6. Then the spindle 62 is lowered, and the polishing pad 66 is pressed against the second face 2b of the first wafer 2, and the second face 2b of the first wafer 2 is polished in this state. Then, as illustrated in an enlarged view in FIG. 8, the polishing pad 66 is elastically deformed at the corner 2c at the outer peripheral end of the first wafer 2 on the second face 2b side, such that the polishing pad 66 inclines downward toward outer side of the first wafer 2 in the diameter direction. As a result, the second face 2b and the corner 2c are polished, and the corner 2c is processed (C chamfering or R chamfering) such that the thickness gradually decreases outward in the diameter direction of the first wafer 2. During polishing, a polishing solution may be supplied to a portion between the polishing pad 66 and the second face 2b.

### Resin Layer Forming

After the corner processing, forming a resin layer by applying liquid resin onto the second face 2b of the first wafer 2 is performed.

### Liquid Resin Supply Apparatus 68

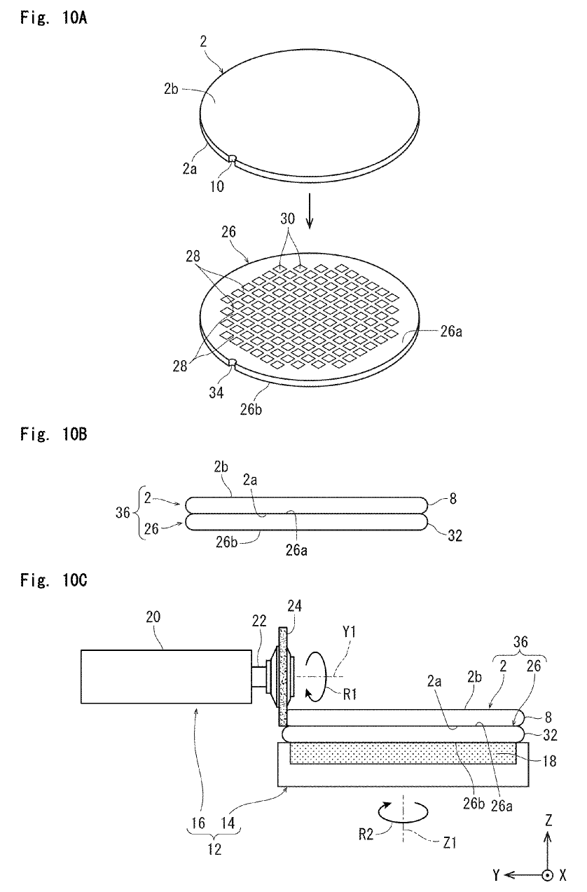

The resin layer forming can be performed using a liquid resin supply apparatus 68 illustrated in FIG. 9A, for example. The liquid resin supply apparatus 68 includes: a chuck table 70 which holds a workpiece; and a liquid resin supply unit 72 which supplies liquid resin to the workpiece held by the chuck table 70.

### Chuck Table 70 of the Liquid Resin Supply Apparatus 68

A disc-shaped suction chuck 74 is disposed at an upper end of the chuck table 70. The suction chuck 74 is formed of a porous member (e.g., porous ceramics), and is connected to a suction pump (not illustrated). In the chuck table 70, a suction force is generated on an upper face of the suction chuck 74 using the suction pump, whereby the workpiece placed on the upper face of the chuck table 70 is suction-held. The chuck table 70 is rotatable around a shaft line Z6 which extends in the Z axis direction, passing through the center of the suction chuck 74.

### Liquid Resin Supply Unit 72 of Liquid Resin Supply Apparatus 68

The liquid resin supply unit 72 includes: a tank (not illustrated) which stores liquid resin; a pump (not illustrated) which delivers the liquid resin in the tank; and a supply pipe 76 which supplies the liquid resin delivered by the pump to the upper face of the workpiece held by the chuck table 70.

In the resin layer forming, the second face 2b of the first wafer 2 is directed upward, and the bonded wafer 36 is suction-held on the upper face of the chuck table 70. Here the center of the first wafer 2 is matched with the shaft line Z6. Then an outlet 76a of the supply pipe 76 of the liquid resin supply unit 72 is positioned above the center of the first wafer 2. Then the chuck table 70 is rotated in a direction indicated by the arrow R6, while dripping the liquid resin 78 from the supply pipe 76 of the liquid resin supply unit 72 onto the first wafer 2. Then the liquid resin 78, which dripped onto the second face 2b of the first wafer 2 spreads over the entire surface of the second face 2b of the first wafer 2 by centrifugal force. Then the liquid resin 78 is solidified so as to form a resin layer 80 on the second face 2b of the first wafer 2 (see FIGS. 9B and 9C).

As described above, in the present embodiment, processing (chamfering) is performed on the corner 2c at the outer peripheral end of the first wafer 2 on the second face 2b side, such that the thickness gradually decreases outward in the diameter direction of the first wafer 2. Therefore the influence of the surface tension which acts on the liquid resin 78 is reduced. Hence according to the present embodiment, the resin layer 80 can be uniformly formed on the ground surface (second surface 2b) of the first wafer 2 after grinding.

In the case of forming a resist film as the resin layer 80, exposure is performed using an appropriate photomask, then development and etching are performed in sequence, and finally the resin layer 80 (resist film) is removed from the second face 2b of the first wafer 2.

### Dividing

After the resin layer forming, manufacturing device chips by dividing the first wafer 2 and the second wafer 26 along the division lines 4 on the first wafer 2, is performed.

The dividing can be performed using the cutting apparatus 12 described above, for example. The thickness of the cutting blade 24 used here is smaller than the width of the division line 4. The dividing is not illustrated, but to perform the dividing using the cutting apparatus 12, the second face 2b of the first wafer 2 is directed upward, and the bonded wafer 36 is suction-held on the upper face of the chuck table 14. Then the bonded wafer 36 is imaged using an imaging unit (not illustrated) of the cutting apparatus 12, and division lines 4 of the first wafer 2 are aligned in the X axis direction based on an image of the bonded wafer 36 captured by the imaging unit. The imaging unit includes: a camera (e.g., infrared camera) which can image inside the first wafer 2 and detect the division lines 4. Then the cutting blade 24 is positioned above the division lines 4 aligned in the X axis direction. Then the cutting edge of the cutting blade 24, rotating at high-speed, is cut into the division lines 4 aligned in the X axis direction, while supplying the cutting water, and the chuck table 14 is fed for processing in the X axis direction. Thus the bonded wafer 36 is cut along the division lines 4.

Then while the cutting blade 24 is index-fed in the Y axis direction by the distance corresponding to an interval of the division lines 4 in the Y axis direction, cutting of the bonded wafer 36 using the cutting blade 24 is repeated. Thereby the bonded wafer 36 is cut along all the division lines 4 aligned in the X axis direction. Then the chuck table 14 is rotated 90°, then the cutting of the bonded wafer 36 and the index-feeding are alternately repeated. Thereby the bonded wafer 36 is cut along all the division lines 4 in the direction intersecting orthogonally with the division lines 4 previously cut. Thus the bonded wafer 36 is cut along the division lines 4 of the first wafer 2, and the device chips are manufactured thereby.

The dividing may be performed using a laser processing apparatus. To perform the dividing using the laser processing apparatus, a condensing point of the laser beam having an absorption wavelength with respect to the bonded wafer 36 is positioned on the upper face of the bonded wafer 36, and the laser beam is applied along the division lines 4 of the first wafer 2, whereby the bonded wafer 36 can be divided along the division lines 4. A condensing point of the laser beam having a transmissive wavelength with respect to the bonded wafer 36 may be positioned inside the bonded wafer 36 instead, and the laser beam is applied along the division lines 4 of the first wafer 2, so as to form modified layers inside the bonded wafer 36 along the division lines 4, then the bonded wafer 36 is divided by applying an external force to the bonded wafer 36.

### Modification 1

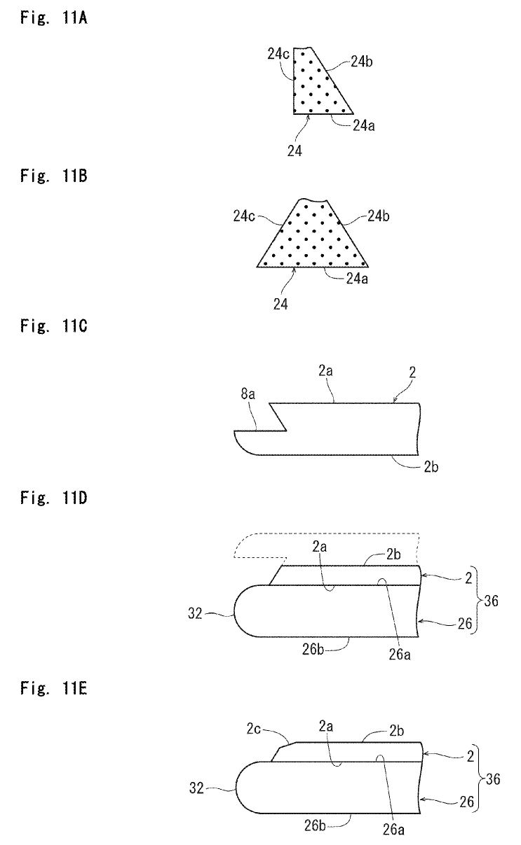

The present disclosure is not limited to the above mentioned embodiment, but may be modified in various ways. In the embodiment described above, the bonding is performed after the chamfer removing, but this order may be reversed, performing the bonding before the chamfer removing. In other words, as illustrated in FIGS. 10A and 10B, the first wafer 2 from which the chamfer 8 is not removed and the second wafer 26 are bonded, then all the chamfer 8 of the first wafer 2 is removed using the cutting apparatus 12, as illustrated in FIG. 10C. In this case, the chamfer 8 is completely removed from the second face 2b side to the first face 2a side.

### Modification 2

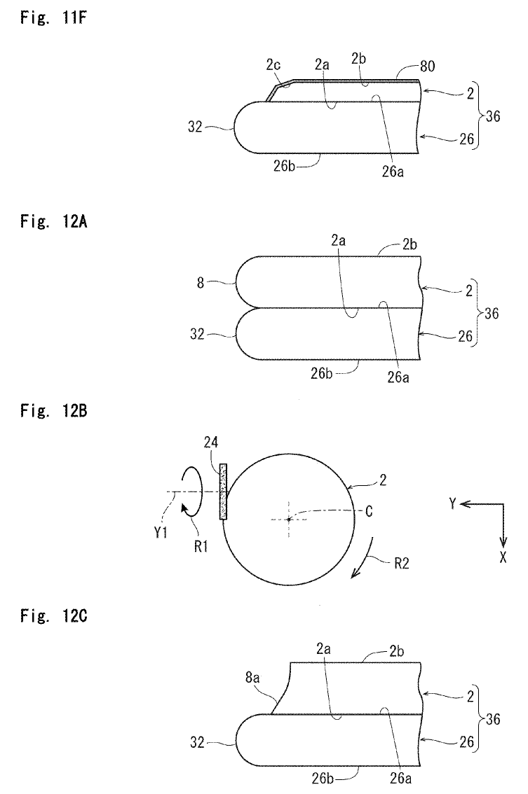

In the embodiment described above, the outer peripheral end of the first wafer 2 after the chamfer removing is vertical to the first face 2a and the second face 2b, but may not be vertical to the first face 2a and the second face 2b. For example, if the chamfer removing is performed using a cutting blade 24 of which first side face 24b is inclined from the outer peripheral end 24a (see FIG. 11A), or using a cutting blade 24 of which the first side face 24b and the second side face 24c are both inclined from the outer peripheral end 24a (see FIG. 11B), the outer peripheral end of the first wafer 2 inclines from the first face 2a and the second face 2b, as illustrated in FIG. 11C. Once the chamfer removing is performed, the bonding and the grinding are sequentially performed, as illustrated in FIG. 11D. In FIG. 11D, the portion ground in the grinding is indicated by the broken line. Then the corner processing is performed, as illustrated in FIG. 11E, so that the inclined faces of which angles, with respect to the first face 2a and the second face 2b, are different (two levels of inclined surfaces), are formed at the outer peripheral end of the first wafer 2. Then the resin layer forming is performed, as illustrated in FIG. 11F. In this case the influence of the surface tension which acts on the liquid resin 78 is further reduced by the two levels of inclined surfaces. This means that uniformity of the thickness of the resin layer 80 can be further improved. FIG. 11F indicates the two levels of inclined surfaces, but three levels of inclined surfaces may be formed. In Modification 2 as well, the R chamfering may be performed in the corner processing.

### Modification 3

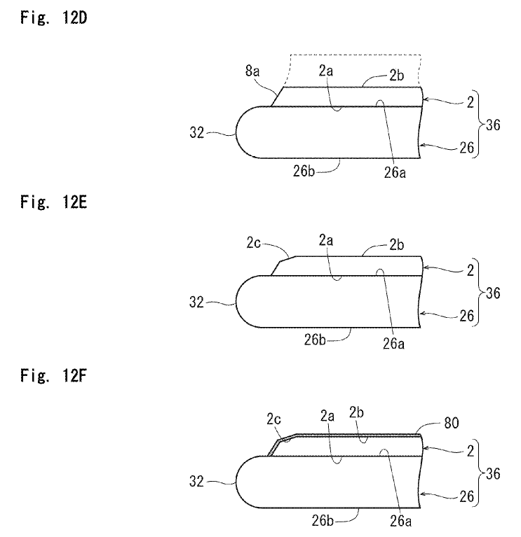

In the case of the chamfer removing after the bonding, if the chamfer removing is performed in a state where the shaft line Y1 of the cutting blade 24 is distant from the center C of the first wafer 2 in the X axis direction, as illustrated in FIGS. 12A and 12B, the outer peripheral end of the first wafer 2 becomes a curved surface, as illustrated in FIG. 12C. In this case as well, when the grinding, the corner processing and the resin layer forming are performed (see FIGS. 12D to 12F), the influence of the surface tension which acts on the liquid resin 78 is further reduced by the curved surface and the inclined surface. This means that uniformity of the thickness of the resin layer 80 can be further improved. The R chamfering may be performed in the corner processing, so that the outer peripheral end of the first wafer 2 has two levels of curved surfaces. In FIG. 12C, only the first wafer 2 is processed in the chamfer removing, but the cutting blade 24 may cut into the second wafer 26 as well.

### Modification 4

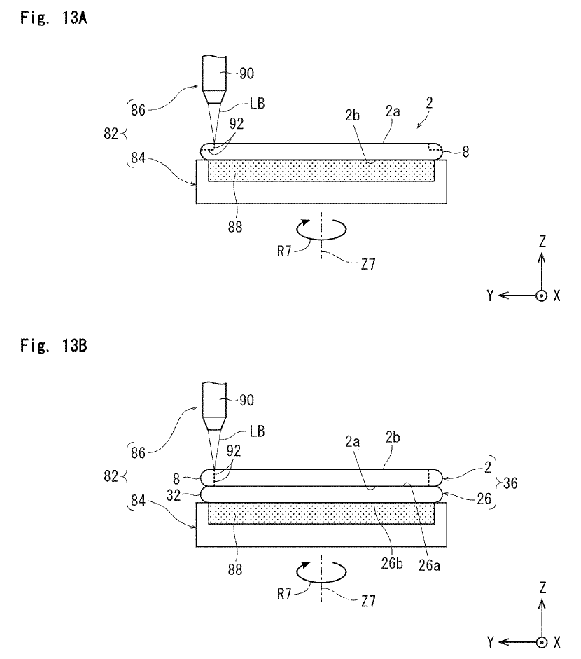

In the embodiment described above, the cutting apparatus 12 is used in the chamfer removing, but a laser processing apparatus 82, illustrated in FIGS. 13A and 13B, may be used. The laser processing apparatus 82 includes: a chuck table 84 which holds a workpiece; and a laser applying unit 86 which applies a laser beam LB onto the workpiece held by the chuck table 84.

### Chuck Table 84 of Laser Processing Apparatus 82

A disc-shaped suction chuck 88 is disposed at an upper end of the chuck table 84. The suction chuck 88 is formed of a porous member (e.g., porous ceramics), and is connected to a suction pump (not illustrated). In the chuck table 84, a suction force is generated on the upper face of the suction chuck 88 using the suction pump, whereby the workpiece placed on the upper face of the chuck table 84 is suction-held. The chuck table 84 is rotatable around a shaft line Z7 which extends in the Z axis direction, passing through the center of the suction chuck 88.

### Laser Applying Unit 86 of Laser Processing Apparatus 82

The laser applying unit 86 includes: an oscillator (not illustrated) which oscillates a laser beam LB having a transmissive wavelength with respect to the first wafer 2; and a condenser 90 which condenses the laser beam LB oscillated by the oscillator.

The chamfer removing by using the laser processing apparatus 82 may be performed before the bonding, or after the bonding. To perform the chamfer removing by using the laser processing apparatus 82 before the bonding, the first face 2a is directed upward, and the first wafer 2 is suction-held on the upper face of the chuck table 84. Here the center of the first wafer 2 is matched with the shaft line Z7. Then the laser beam LB having a transmissive wavelength with respect to the first wafer 2 is applied onto the first wafer 2, while rotating the chuck table 84 in a direction indicated by an arrow R7, and a modified layer 92 is formed in a ring shape along the outer peripheral end of the first wafer 2. Then the condensing position of the laser beam LB is changed, and the laser beam LB is applied onto the first wafer 2 in the same manner. The change of the condensing position and applying the laser beam LB are repeated like this, whereby a plurality of ring-shaped modified layers 92 are formed, as illustrated in FIG. 13A, such that the entire shape of the modified layers 92 in the cross-section becomes L-shaped. To perform the chamfer removing by using the laser processing apparatus 82 after the bonding, the change of the condensing position and applying of the laser beam LB are repeated, whereby a plurality of ring-shaped modified layers 92 are formed, as illustrated in FIG. 13B, such that the entire shape of the modified layers 92 become I-shaped, which extends in the vertical direction. When the grinding is performed thereafter, along the modified layers 92 at least a part of the chamfer 8 of the first wafer 2 is annularly removed along the outer periphery of the first wafer 2.

As described above, in the present embodiment, the corner 2c at the outer peripheral end of the first wafer 2 on the second face 2b side is processed (chamfering) such that thickness gradually decreases outward in the diameter direction, hence the influence of the surface tension which acts on the liquid resin 78 can be reduced. Hence according to the present embodiment, the resin layer 80 can be uniformly formed on the ground surface (second surface 2b) of the first wafer 2 after grinding.

### REFERENCE SIGNS LIST

2 First wafer

2a First face

2b Second face

2c Corner

4 Division line

6 Device

8 Chamfer

24 Cutting blade

26 Second wafer

26a First face

26b Second face

28 Division line

30 Device

32 Chamfer

50 Grinding wheel

52 Grinding stone

66 Polishing pad

78 Liquid resin

80 Resin layer

What is claimed is:

1. A wafer processing method for processing a first wafer which includes a first face and a second face on an opposite side to the first face, and in which a chamfer is formed on an outer peripheral end, the method comprising:
chamfer removing at least a part of the chamfer of the first wafer in annular shape along an outer periphery of the first wafer;
bonding the first face of the first wafer with a second wafer;
grinding the second face of the first wafer by using a grinding wheel which includes grinding stones arranged annularly, after the chamfer removing and the bonding;
corner processing of processing, after the grinding, a corner of the outer peripheral end of the first wafer on the second face side ground in the grinding, such that thickness thereof gradually decreases outward in a diameter direction; and
resin layer forming by applying liquid resin onto the second face of the first wafer, after the corner processing.

2. The wafer processing method of claim 1, wherein
the bonding is performed after the chamfer removing.

3. The wafer processing method of claim 1, wherein
the bonding is performed before the chamfer removing.

4. The wafer processing method of claim 1, wherein
in the corner processing of processing by using the grinding wheel, by relatively moving the grinding wheel and the first wafer.

5. The wafer processing method of claim 2, wherein
in the corner processing of processing by using the grinding wheel, by relatively moving the grinding wheel and the first wafer.

6. The wafer processing method of claim 3, wherein
in the corner processing of processing by using the grinding wheel, by relatively moving the grinding wheel and the first wafer.

7. The wafer processing method of claim 1, wherein
in the corner processing of processing by using an annular cutting blade having a cutting edge on an outer periphery, by relatively moving the cutting blade and the first wafer.

8. The wafer processing method of claim 2, wherein
in the corner processing of processing by using an annular cutting blade having a cutting edge on an outer periphery, by relatively moving the cutting blade and the first wafer.

9. The wafer processing method of claim 3, wherein
in the corner processing of processing by using an annular cutting blade having a cutting edge on an outer periphery, by relatively moving the cutting blade and the first wafer.

10. The wafer processing method of claim 1, wherein
in the corner processing of processing along with polishing the second face of the first wafer by using a polishing pad.

11. The wafer processing method of claim 2, wherein
in the corner processing of processing along with polishing the second face of the first wafer by using a polishing pad.

12. The wafer processing method of claim 3, wherein
in the corner processing of processing along with polishing the second face of the first wafer by using a polishing pad.

13. A device chip manufacturing method, comprising:
chamfer removing at least a part of a chamfer of a first wafer in annular shape along an outer periphery of the first wafer, the first wafer including a first face on which a device is formed in each of a plurality of regions demarcated by a plurality of division lines, and a second face on an opposite side to the first face, and the chamfer being formed on an outer peripheral end of the first wafer;
bonding the first face of the first wafer with a second wafer;
grinding the second face of the first wafer by using a grinding wheel which includes grinding stones arranged annularly, after the chamfer removing and the bonding;
corner processing of processing, after the grinding, a corner of an outer peripheral end of the first wafer on the second face side ground in the grinding, such that thickness thereof gradually decreases outward in a diameter direction;
resin layer forming by applying liquid resin onto the second face of the first wafer, after the corner processing; and
manufacturing device chips by dividing the first wafer and the second wafer along the division lines on the first wafer, after the resin layer forming.
